(19) United States
(12) Patent Application Publication
(10) Pub. No.: US 2023/0137101 A1
(43) Pub. Date: May 4, 2023

(54) Integrated Circuit Structure of N-Type and P-Type FinFET Transistors

(71) Applicant: Shanghai Huali Integrated Circuit Corporation, Shanghai (CN)

(72) Inventor: Wenyin Weng, Shanghai (CN)

(73) Assignee: Shanghai Huali Integrated Circuit Corporation, Shanghai (CN)

(21) Appl. No.: 17/951,524

(22) Filed: Sep. 23, 2022

(30) Foreign Application Priority Data
Nov. 3, 2021 (CN) 202111292193.9

(51) Int. Cl. H01L 27/098; H01L 29/78

(52) U.S. Cl. CPC H01L 27/098; H01L 29/785

(57) ABSTRACT

The present application discloses an integrated circuit structure of N-type and P-type fin transistors, wherein the N-type and P-type fin transistors are respectively formed on first and second fins, first and second diffusion breakdown structures are respectively provided on the first and second fins. A first dielectric layer of the first diffusion breakdown structure is made of a stress material to enable the first diffusion breakdown structure to have a first stress. A second dielectric layer of the second diffusion breakdown structure is made of a stress material to enable the second diffusion breakdown structure to have a second stress different from the first stress. The first stress is configured according to a requirement of improving carrier mobility of a first channel area, and the second stress is configured according to a requirement of improving carrier mobility of a second channel area.

### CROSS-REFERENCE TO RELATED APPLICATIONS

This application claims the priority to Chinese patent application No. 202111292193.9, filed on Nov. 3, 2021, the disclosure of which is incorporated herein by reference in its entirety.

### TECHNICAL FIELD

The present application relates to a semiconductor integrated circuit, in particular to an integrated circuit structure of N-type and P-type FinFET transistors.

### BACKGROUND

FIG. 1 is a diagram of a sectional structure of an existing single diffusion breakdown (SDB) structure. A plurality of fins 101 formed by patterning a semiconductor substrate are formed on the semiconductor substrate. According to the type of a device to be formed, the fin 101 is doped to form a doping diffusion area. For example, in a formation area of an N-type fin transistor, a P-type diffusion area is formed in the fin 101, and in a formation area of a P-type fin transistor, an N-type diffusion area is formed in the fin 101.

A plurality of transistors is formed on one fin 101. In order to prevent electrical interference between adjacent transistors, it is necessary to break down the diffusion area on the fin 101. A plurality of SDBs 102 are formed on the fin 101 shown in FIG. 1, and the SDB 102 breaks down the diffusion area of the fin 101 into an area indicated by a dashed line box 104. The area 104 serves as an active area for forming the transistor. The SDB process technology is ususally employed in process nodes below 14 nm.

A gate structure 103 of the transistor covers a top surface and a side surface of the fin 101. The gate structure 103, i.e., a metal gate structure, includes a gate dielectric layer, a work function metal layer, and a metal conductive material layer. Generally, the metal conductive material layers of the gate structures 103 of the transistors which are located in the same column with gates thereof connected to one another are connected together to form a gate strip structure perpendicular to the fin 101. The surface of the active area 104 covered by the gate structure 103 is used for forming a conductive channel.

A formation area of the gate structure 103 is usually defined by means of a dummy polysilicon gate 103a. Subsequently, the dummy polysilicon gate 103a is removed, and the gate structure 103 is formed in an area where the dummy polysilicon gate 103a is removed. After the gate structure 103 is formed, the dummy polysilicon gate 103a in the formation area of the gate structure 103 is not shown in FIG. 1.

The dummy polysilicon gates 103a each have a strip structure perpendicular to the fin 101 and are arranged at intervals, e.g., equal intervals. Referring to FIG. 1, a formation area of the SDB 102 is located at the bottom of a corresponding dummy polysilicon gate 103a. The SDB 102 is formed by etching the fin 101 at the bottom of the dummy polysilicon gate 103a to form a trench and then filling the trench with a dielectric layer. In FIG. 1, in order to show a relationship between the SDB 102 and the dummy polysilicon gate 103a, the dummy polysilicon gate 103a is retained. Actually, the dummy polysilicon gate 103a on the top of the SDB 102 can also be removed according to actual needs, and a removal area may be filled with a dielectric layer or a material the same as that of the gate structure 103.

FIG. 2 is a diagram of a sectional structure of an existing double diffusion breakdown (DDB) structure. A plurality of DDBs 202 is formed on a fin 201, and the DDB 202 breaks down a diffusion area on the fin 201 to form an active area 204. A transistor is formed on the active area 204, and a gate structure 203 of the transistor covers a top surface and a side surface of the fin 201 at the active area 204. The surface of the active area 204 covered by the gate structure 203 is used for forming a conductive channel. Different from the SDB structure shown in FIG. 1, a formation area of the DDB 202 is located between two dummy polysilicon gates 203a.

The following differences exist between the SDB and DDB.

The device density of a chip adopting the SDB is greater than the device density of a chip adopting the DDB.

The insulation leakage performance of the SDB is poorer than the insulation leakage performance of the DDB.

The area of a chip adopting the SDB is less than the area of a chip adopting the DDB.

The process difficulty of the SDB is greater than the process difficulty of the DDB.

In integrated circuits, inverters are widely used as basic circuits. FIG. 3 is a circuit diagram of an existing inverter. The inverter is formed by connecting a PMOS transistor 301 and an NMOS transistor 302. A gate of the PMOS transistor 301 and a gate of the NMOS transistor 302 are connected together and used as an input end IN. A drain of the PMOS transistor 301 and a drain of the NMOS transistor 302 are connected together and used as an output end OUT. A source of the PMOS transistor 301 is connected to a power supply voltage Vcc, and a source of the NMOS transistor 302 is connected to the ground Gnd.

FIG. 4 is a layout of a first existing inverter. In the first existing inverter, formation areas of a NMOS transistor and a PMOS transistor both adopt the SDB structure. In FIG. 4, the formation area of the PMOS transistor, i.e., P-type fin transistor, is indicated by a dashed line box 301a, and the formation area of the NMOS transistor, i.e., N-type fin transistor, is indicated by a dashed line box 302a. Metal conductive material layers 403 of gate structures of the PMOS transistor and the NMOS transistor are connected together to form a strip shape.

A section of the PMOS transistor along a dashed line AA1 has a structure as shown in FIG. 1, and an active area 404a of the PMOS transistor is defined by means of the SDB.

Similarly, a section of the NMOS transistor along a dashed line BB1 has a structure as shown in FIG. 1, and an active area 404b of the NMOS transistor is defined by means of the SDB.

Drain areas of the PMOS transistor and the NMOS transistor are connected to each other by means of a corresponding contact 402 and a metal wire formed by a front metal layer 401. A source area of the PMOS transistor is connected to a power supply voltage Vcc by means of the corresponding contact 402 and the metal wire formed by the front metal layer 401. A source area of the NMOS transistor is connected to the ground Gnd by means of the corresponding contact 402 and the metal wire formed by the front metal layer 401.

FIG. 5 is a layout of a second existing inverter. In the second existing inverter, formation areas of a NMOS transistor and a PMOS transistor both adopt the DDB structure. In FIG. 5, the formation area of the PMOS transistor is indicated by a dashed line box 301b, and the formation area of the NMOS transistor is indicated by a dashed line box 302b. Metal conductive material layers 503 of gate structures of the PMOS transistor and the NMOS transistor are connected together to form a strip shape.

A section of the PMOS transistor along a dashed line AA2 has a structure as shown in FIG. 2, and an active area 504a of the PMOS transistor is defined by means of the DDB.

Similarly, a section of the NMOS transistor along a dashed line BB2 has a structure as shown in FIG. 2, and an active area 504b of the NMOS transistor is defined by means of the DDB.

Drain areas of the PMOS transistor and the NMOS transistor are connected to each other by means of a corresponding contact 502 and a metal wire formed by a front metal layer 501. A source area of the PMOS transistor is connected to a power supply voltage Vcc by means of the corresponding contact 502 and the metal wire formed by the front metal layer 501. A source area of the NMOS transistor is connected to the ground Gnd by means of the corresponding contact 502 and the metal wire formed by the front metal layer 501.

In the first existing inverter shown in FIG. 4, the PMOS transistor and the NMOS transistor both adopt the SDB to achieve isolation. However, SDB isolation cannot achieve improvement to the performances of both the PMOS transistor and the NMOS transistor. Generally, a dielectric layer filled with the SDB is an oxide layer with a compressive stress formed by means of flowable chemical vapor deposition (FCVD). In this case, the SDB is conducive to the improvement to the performance of the PMOS transistor, but is not conducive to the improvement to the performance of the NMOS transistor. Similarly, in the second existing inverter shown in FIG. 5, DDB isolation likewise cannot achieve improvement to the performances of both the PMOS transistor and the NMOS transistor.

### BRIEF SUMMARY

The present application provides an integrated circuit structure of N-type and P-type FinFET transistors, so as to eliminate an adverse impact of a stress of a diffusion breakdown structure of a fin on the performance of the transistor and improve the performances of both the N-type and P-type FinFET transistors by means of the stress of the diffusion breakdown structure of the fin.

According to some embodiments in this application, the integrated circuit structure of N-type and P-type FinFET transistors provided by the present application is formed on a semiconductor substrate.

A plurality of strip-shaped fins is formed on the semiconductor substrate.

Each N-type fin transistor is formed on a first fin, and a P-type diffusion area is formed on the first fin.

Each P-type fin transistor is formed on a second fin, and an N-type diffusion area is formed on the second fin.

A first diffusion breakdown structure for breaking down the P-type diffusion area is provided on the first fin.

A second diffusion breakdown structure for breaking down the N-type diffusion area is provided on the second fin.

The first diffusion breakdown structure is composed of a first dielectric layer filling a first trench.

The second diffusion breakdown structure is composed of a second dielectric layer filling a second trench.

A first gate structure of the N-type fin transistor covers a top surface and a side surface of the first fin, and the P-type diffusion area in the first fin covered by the first gate structure forms a first channel area of the N-type fin transistor.

A second gate structure of the P-type fin transistor covers a top surface and a side surface of the second fin, and the N-type diffusion area in the second fin covered by the second gate structure forms a second channel area of the P-type fin transistor.

The first dielectric layer is made of a stress material to enable the first diffusion breakdown structure to have a first stress.

The second dielectric layer is made of a stress material to enable the second diffusion breakdown structure to have a second stress, the second stress being different from the first stress.

The first stress is configured according to a requirement of improving carrier mobility of the first channel area, and the second stress is configured according to a requirement of improving carrier mobility of the second channel area.

In some cases, the first dielectric layer and the second dielectric layer are made of the same compressive stress material; the first stress and the second stress are both compressive stresses; according to a characteristic of the compressive stress material being capable of improving electron mobility, the width of the first trench is configured to be greater than the width of the second trench, so that the first stress is greater than the second stress; the carrier mobility of the first channel area is increased by means of the larger first stress, so as to improve the performance of the N-type fin transistor; and a decrease in the carrier mobility of the second channel area is reduced by means of the smaller second stress, so as to prevent performance degradation of the P-type fin transistor.

In some cases, the compressive stress material of which the first dielectric layer and the second dielectric layer are made is an oxide formed by means of FCVD.

In some cases, the first diffusion breakdown structure is a double diffusion breakdown structure, and the first trench is formed by etching the first fin between two dummy gate structures.

In some cases, the second diffusion breakdown structure is a single diffusion breakdown structure, and the second trench is formed by etching the second fin at the bottom of a dummy gate structure.

In some cases, the first dielectric layer and the second dielectric layer are made of the same tensile stress material; the first stress and the second stress are both tensile stresses; according to a characteristic of the tensile stress material being capable of improving hole mobility, the width of the second trench is configured to be greater than the width of the first trench, so that the second stress is greater than the first stress; the carrier mobility of the second channel area is increased by means of the larger second stress, so as to improve the performance of the P-type fin transistor; and a decrease in the carrier mobility of the first channel area is reduced by means of the smaller first stress, so as to prevent performance degradation of the N-type fin transistor.

In some cases, the second diffusion breakdown structure is a double diffusion breakdown structure, and the second trench is formed by etching the second fin between two dummy gate structures.

In some cases, the first diffusion breakdown structure is a single diffusion breakdown structure, and the first trench is formed by etching the first fin at the bottom of a dummy gate structure.

In some cases, a source area and a drain area of the N-type fin transistor are formed in the first fins on two sides of the first gate structure.

A source area and a drain area of the P-type fin transistor are formed in the second fins on two sides of the second gate structure.

In some cases, a first embedded epitaxial layer is formed in the source area and the drain area of the N-type fin transistor.

In some cases, the material of the first embedded epitaxial layer includes SiP.

In some cases, a second embedded epitaxial layer is formed in the source area and the drain area of the P-type fin transistor.

In some cases, the material of the second embedded epitaxial layer includes SiGe.

In some cases, the integrated circuit structure includes a CMOS inverter; and the CMOS inverter consists of one of the N-type fin transistors and one of the P-type fin transistors connected to each other.

In some cases, in a top view, each of the first fins and each of the second fins are arranged in parallel.

The first gate structure includes a first gate dielectric layer, an N-type work function metal layer, and a metal conductive material layer stacked in sequence.

The second gate structure includes a second gate dielectric layer, a P-type work function metal layer, and a metal conductive material layer stacked in sequence.

In the CMOS inverter, the metal conductive material layer of the first gate structure of the N-type fin transistor and the metal conductive material layer of the second gate structure of the P-type fin transistor are connected to form an integral gate strip structure, and the gate strip structure is perpendicular to a strip extending direction of the first fin and the second fin.

In the prior art, the same diffusion breakdown structure is adopted in fins of an N-type fin transistor and a P-type fin transistor, e.g., SDB or DDB, resulting in a defect of incapability of improvement to the performances of both the N-type fin transistor and the P-type fin transistor. In the present application, the first diffusion breakdown structure on the first fin corresponding to the N-type fin transistor and the second diffusion breakdown structure on the second fin corresponding to the P-type fin transistor are configured independently, and the first diffusion breakdown structure and the second diffusion breakdown structure are configured according to the requirements of improving the performances of the N-type fin transistor and the P-type fin transistor, respectively, so that the first stress of the first diffusion breakdown structure can improve the performance of the N-type fin transistor and the second stress of the second diffusion breakdown structure can improve the performance of the P-type fin transistor. Therefore, the present application can eliminate an adverse impact of the stress of the diffusion breakdown structure of the fin on the performance of the transistor and improve the performances of both the N-type and P-type FinFET transistors by means of the stress of the diffusion breakdown structure of the fin.

### BRIEF DESCRIPTION OF THE DRAWINGS

The present application is described in detail below with reference to the drawings and specific implementations:

FIG. 1 is a diagram of a sectional structure of an existing single diffusion breakdown structure.

FIG. 2 is a diagram of a sectional structure of an existing double diffusion breakdown structure.

FIG. 3 is a circuit diagram of an existing inverter.

FIG. 4 is a layout of a first existing inverter.

FIG. 5 is a layout of a second existing inverter.

FIG. 6 is a layout of an integrated circuit structure of N-type and P-type fin transistors according to an embodiment of the present application.

FIG. 7 is an enlarged view of an inverter corresponding to a dashed line box 601 in FIG. 6.

FIG. 8 is a sectional view along a dashed line AA in FIG. 6.

FIG. 9 is a sectional view along a dashed line BB in FIG. 6.

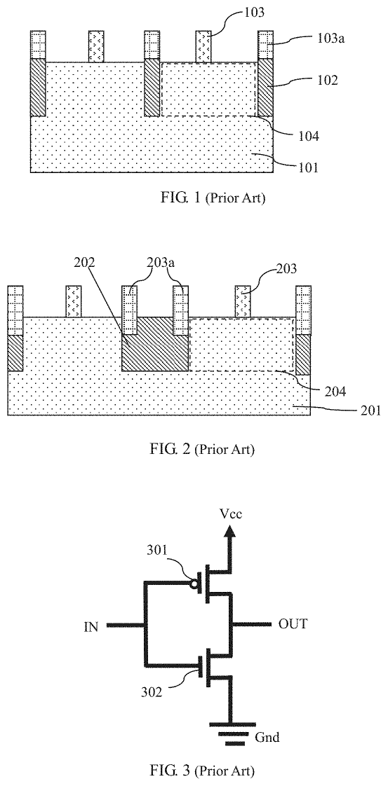

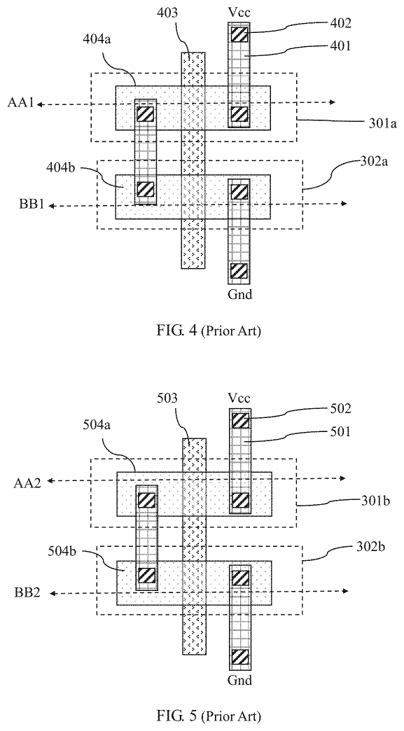

### DETAILED DESCRIPTION

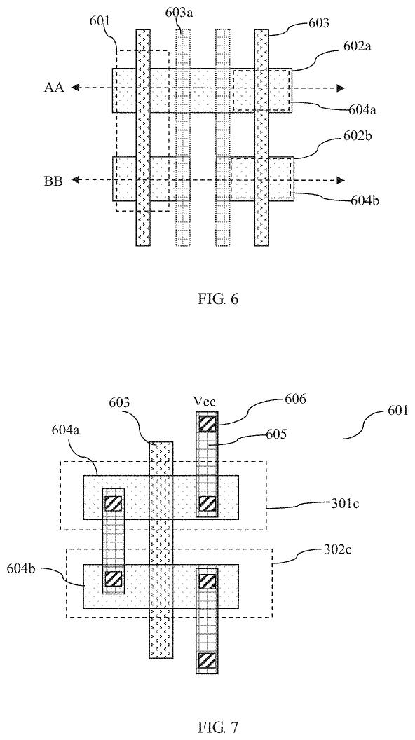

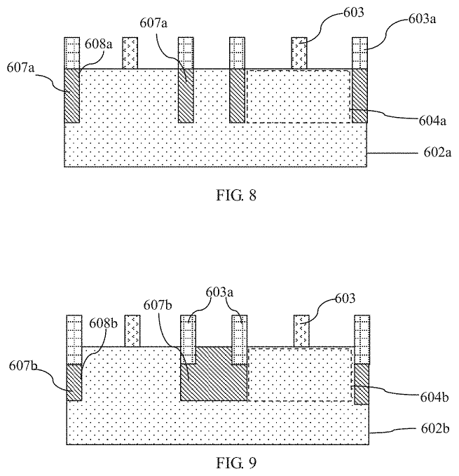

FIG. 6 is a layout of an integrated circuit structure of N-type and P-type fin transistors according to an embodiment of the present application. FIG. 7 is an enlarged view of an inverter corresponding to a dashed line box 601 in FIG. 6. FIG. 8 is a sectional view along a dashed line AA in FIG. 6. FIG. 9 is a sectional view along a dashed line BB in FIG. 6. The integrated circuit structure of N-type and P-type fin transistors in this embodiment of the present application is formed on a semiconductor substrate.

Referring to FIG. 6, a plurality of strip-shaped fins are formed on the semiconductor substrate.

Each N-type fin transistor is formed on a first fin 602b, and a P-type diffusion area is formed on the first fin 602b.

Each P-type fin transistor is formed on a second fin 602a, and an N-type diffusion area is formed on the second fin 602a.

Referring to FIG. 6 and FIG. 9, a first diffusion breakdown structure 607b for breaking down the P-type diffusion area is provided on the first fin 602b. After being broken down by the first diffusion breakdown structure 607b, the P-type diffusion area located between the two first diffusion breakdown structures 607b serves as an active area for forming the N-type fin transistor and is marked by a mark 604b independently.

Referring to FIG. 6 and FIG. 8, a second diffusion breakdown structure 607a for breaking down the N-type diffusion area is provided on the second fin 602a. After being broken down by the second diffusion breakdown structure 607a, the N-type diffusion area located between the two second diffusion breakdown structures 607a serves as an active area for forming the P-type fin transistor and is marked by a mark 604a independently.

Referring to FIG. 8, the first diffusion breakdown structure 607b is composed of a first dielectric layer filling a first trench 608b.

Referring to FIG. 9, the second diffusion breakdown structure 607a is composed of a second dielectric layer filling a second trench 608a.

A first gate structure of the N-type fin transistor covers a top surface and a side surface of the first fin 602b, and the P-type diffusion area in the first fin 602b covered by the first gate structure forms a first channel area of the N-type fin transistor.

A second gate structure of the P-type fin transistor covers a top surface and a side surface of the second fin 602a, and the N-type diffusion area in the second fin 602a covered by the second gate structure forms a second channel area of the P-type fin transistor.

In this embodiment of the present application, the integrated circuit structure includes a CMOS inverter. Referring to FIG. 7, the CMOS inverter consists of one of the N-type fin transistors and one of the P-type fin transistors connected to each other. In FIG. 7, a formation area of the N-type fin transistor is marked with 302c, and a formation area of the P-type fin transistor is marked with 301c.

Referring to FIG. 6, in a top view, each of the first fins 602b and each of the second fins 602a are arranged in parallel.

The first gate structure includes a first gate dielectric layer, an N-type work function metal layer, and a metal conductive material layer stacked in sequence.

The second gate structure includes a second gate dielectric layer, a P-type work function metal layer, and a metal conductive material layer stacked in sequence.

In the CMOS inverter, the metal conductive material layer of the first gate structure of the N-type fin transistor and the metal conductive material layer of the second gate structure of the P-type fin transistor are connected to form an integral gate strip structure 603, and the gate strip structure 603 is perpendicular to a strip extending direction of the first fin 602b and the second fin 602a.

The first dielectric layer is made of a stress material to enable the first diffusion breakdown structure 607b to have a first stress.

The second dielectric layer is made of a stress material to enable the second diffusion breakdown structure 607a to have a second stress, the second stress being different from the first stress.

The first stress is configured according to a requirement of improving carrier mobility of the first channel area, and the second stress is configured according to a requirement of improving carrier mobility of the second channel area.

In this embodiment of the present application, the first dielectric layer and the second dielectric layer are made of the same compressive stress material; the first stress and the second stress are both compressive stresses; according to a characteristic of the compressive stress material being capable of improving electron mobility, the width of the first trench 608b is configured to be greater than the width of the second trench 608a, so that the first stress is greater than the second stress; the carrier mobility of the first channel area is increased by means of the larger first stress, so as to improve the performance of the N-type fin transistor; and a decrease in the carrier mobility of the second channel area is reduced by means of the smaller second stress, so as to prevent performance degradation of the P-type fin transistor.

In some examples, the compressive stress material of which the first dielectric layer and the second dielectric layer are made is an oxide formed by means of FCVD.

Referring to FIG. 9, the first diffusion breakdown structure 607b is a double diffusion breakdown structure, and the first trench 608b is formed by etching the first fin 603b between two dummy gate structures 603a.

Referring to FIG. 8, the second diffusion breakdown structure 607a is a single diffusion breakdown structure, and the second trench 608a is formed by etching the second fin 602a at the bottom of a dummy gate structure 603a.

In other embodiments, the first dielectric layer and the second dielectric layer are made of the same tensile stress material; the first stress and the second stress are both tensile stresses; according to a characteristic of the tensile stress material being capable of improving hole mobility, the width of the second trench 608a is configured to be greater than the width of the first trench 608b, so that the second stress is greater than the first stress; the carrier mobility of the second channel area is increased by means of the larger second stress, so as to improve the performance of the P-type fin transistor; and a decrease in the carrier mobility of the first channel area is reduced by means of the smaller first stress, so as to prevent performance degradation of the N-type fin transistor. The second diffusion breakdown structure 607a is a double diffusion breakdown structure, and the second trench 608a is formed by etching the second fin 602a between two dummy gate structures 603a. The first diffusion breakdown structure 607b is a single diffusion breakdown structure, and the first trench 608b is formed by etching the first fin 602b at the bottom of a dummy gate structure 603a.

A source area and a drain area of the N-type fin transistor are formed in the first fins 602b on two sides of the first gate structure. In some examples, a first embedded epitaxial layer is formed in the source area and the drain area of the N-type fin transistor. The material of the first embedded epitaxial layer includes SiP.

A source area and a drain area of the P-type fin transistor are formed in the second fins 602a on two sides of the second gate structure. A second embedded epitaxial layer is formed in the source area and the drain area of the P-type fin transistor. The material of the second embedded epitaxial layer includes SiGe.

Referring to FIG. 7, the drain areas of the PMOS transistor and the NMOS transistor in the CMOS inverter are connected to each other by means of a corresponding contact 606 and a metal wire formed by a front metal layer 605. The source area of the PMOS transistor is connected to a power supply voltage Vcc by means of the corresponding contact 606 and the metal wire formed by the front metal layer 605. The source area of the NMOS transistor is connected to the ground Gnd by means of the corresponding contact 606 and the metal wire formed by the front metal layer 605.

In the prior art, the same diffusion breakdown structure is adopted in fins of an N-type fin transistor and a P-type fin transistor, e.g., SDB or DDB, resulting in a defect of incapability of improvement to the performances of both the N-type fin transistor and the P-type fin transistor. In the present application, the first diffusion breakdown structure 607b on the first fin 602b corresponding to the N-type fin transistor and the second diffusion breakdown structure 607a on the second fin 602a corresponding to the P-type fin transistor are configured independently, and the first diffusion breakdown structure 607b and the second diffusion breakdown structure 607a are configured according to the requirements of improving the performances of the N-type fin transistor and the P-type fin transistor, respectively, so that the first stress of the first diffusion breakdown structure 607b can improve the performance of the N-type fin transistor and the second stress of the second diffusion breakdown structure 607a can improve the performance of the P-type fin transistor. Therefore, the present application can eliminate an adverse impact of the stress of the diffusion breakdown structure of the fin on the performance of the transistor and improve the performances of both the N-type and P-type FinFET transistors by means of the stress of the diffusion breakdown structure of the fin. In this way, the performance of the integrated circuit structure formed by both the N-type and P-type fin transistors can be improved, for example, parameters corresponding to a direct drain quiescent current (IDDQ) and an operation speed of the CMOS can be improved.

The present application is described in detail above by using specific embodiments, which, however, are not intended to limit the present application. Without departing from the principles of the present application, those skilled in the art can also make many modifications and improvements, which should also be regarded as the scope of protection of the present application.

What is claimed is:

1. An integrated circuit structure of N-type and P-type fin transistors, wherein the integrated circuit structure is formed on a semiconductor substrate;
a plurality of strip-shaped fins are formed on the semiconductor substrate;
each N-type fin transistor is formed on a first fin, and a P-type diffusion area is formed on the first fin;
each P-type fin transistor is formed on a second fin, and an N-type diffusion area is formed on the second fin;
a first diffusion breakdown structure for breaking down the P-type diffusion area is provided on the first fin;
a second diffusion breakdown structure for breaking down the N-type diffusion area is provided on the second fin;
the first diffusion breakdown structure is composed of a first dielectric layer filling a first trench;
the second diffusion breakdown structure is composed of a second dielectric layer filling a second trench;
a first gate structure of the N-type fin transistor covers a top surface and a side surface of the first fin, and the P-type diffusion area in the first fin covered by the first gate structure forms a first channel area of the N-type fin transistor;
a second gate structure of the P-type fin transistor covers a top surface and a side surface of the second fin, and the N-type diffusion area in the second fin covered by the second gate structure forms a second channel area of the P-type fin transistor;
the first dielectric layer is made of a stress material to enable the first diffusion breakdown structure to have a first stress;
the second dielectric layer is made of a stress material to enable the second diffusion breakdown structure to have a second stress, the second stress being different from the first stress; and
the first stress is configured according to a requirement of improving carrier mobility of the first channel area, and the second stress is configured according to a requirement of improving carrier mobility of the second channel area.

2. The integrated circuit structure of N-type and P-type fin transistors according to claim 1, wherein the first dielectric layer and the second dielectric layer are made of a same compressive stress material; the first stress and the second stress are both compressive stresses; according to a characteristic of the compressive stress material being capable of improving electron mobility, a width of the first trench is configured to be greater than a width of the second trench, so that the first stress is greater than the second stress; the carrier mobility of the first channel area is increased by means of the larger first stress, so as to improve a performance of the N-type fin transistor; and a decrease in the carrier mobility of the second channel area is reduced by means of the smaller second stress, so as to prevent performance degradation of the P-type fin transistor.

3. The integrated circuit structure of N-type and P-type fin transistors according to claim 2, wherein the compressive stress material of which the first dielectric layer and the second dielectric layer are made is an oxide formed by means of flowable chemical vapor deposition (FCVD).

4. The integrated circuit structure of N-type and P-type fin transistors according to claim 3, wherein the first diffusion breakdown structure is a double diffusion breakdown structure, and the first trench is formed by etching the first fin between two dummy gate structures.

5. The integrated circuit structure of N-type and P-type fin transistors according to claim 3, wherein the second diffusion breakdown structure is a single diffusion breakdown structure, and the second trench is formed by etching the second fin at a bottom of a dummy gate structure.

6. The integrated circuit structure of N-type and P-type fin transistors according to claim 1, wherein the first dielectric layer and the second dielectric layer are made of a same tensile stress material; the first stress and the second stress are both tensile stresses; according to a characteristic of the tensile stress material being capable of improving hole mobility, a width of the second trench is configured to be greater than a width of the first trench, so that the second stress is greater than the first stress; the carrier mobility of the second channel area is increased by means of the larger second stress, so as to improve a performance of the P-type fin transistor; and a decrease in the carrier mobility of the first channel area is reduced by means of the smaller first stress, so as to prevent performance degradation of the N-type fin transistor.

7. The integrated circuit structure of N-type and P-type fin transistors according to claim 6, wherein the second diffusion breakdown structure is a double diffusion breakdown structure, and the second trench is formed by etching the second fin between two dummy gate structures.

8. The integrated circuit structure of N-type and P-type fin transistors according to claim 6, wherein the first diffusion breakdown structure is a single diffusion breakdown structure, and the first trench is formed by etching the first fin at a bottom of a dummy gate structure.

9. The integrated circuit structure of N-type and P-type fin transistors according to claim 1, wherein:
a source area and a drain area of the N-type fin transistor are formed in the first fins on two sides of the first gate structure; and
a source area and a drain area of the P-type fin transistor are formed in the second fins on two sides of the second gate structure.

10. The integrated circuit structure of N-type and P-type fin transistors according to claim 9, wherein a first embedded epitaxial layer is formed in the source area and the drain area of the N-type fin transistor.

11. The integrated circuit structure of N-type and P-type fin transistors according to claim 10, wherein a material of the first embedded epitaxial layer comprises SiP.

12. The integrated circuit structure of N-type and P-type fin transistors according to claim 9, wherein a second embedded epitaxial layer is formed in the source area and the drain area of the P-type fin transistor.

13. The integrated circuit structure of N-type and P-type fin transistors according to claim 12, wherein a material of the second embedded epitaxial layer comprises SiGe.

14. The integrated circuit structure of N-type and P-type fin transistors according to claim 1, wherein the integrated circuit structure comprises a CMOS inverter; and the CMOS inverter consists of one of the N-type fin transistors and one of the P-type fin transistors connected to each other.

15. The integrated circuit structure of N-type and P-type fin transistors according to claim 14, wherein in a top view, each of the first fins and each of the second fins are arranged in parallel;
the first gate structure comprises a first gate dielectric layer, an N-type work function metal layer, and a metal conductive material layer stacked in sequence;
the second gate structure comprises a second gate dielectric layer, a P-type work function metal layer, and a metal conductive material layer stacked in sequence; and
in the CMOS inverter, the metal conductive material layer of the first gate structure of the N-type fin transistor and the metal conductive material layer of the second gate structure of the P-type fin transistor are connected to form an integral gate strip structure, and the integral gate strip structure is perpendicular to a strip extending direction of the first fin and the second fin.
